(19) United States
(12) Patent Application Publication
(10) Pub. No.: US 2018/0309044 A1
(43) Pub. Date: Oct. 25, 2018

(54) PIEZOELECTRIC RESONATOR DEVICE

(71) Applicant: Daishinku Corporation, Kakogawa-shi, Hyogo (JP)

(72) Inventor: Masashi HIRAI, Kakogawa-shi (JP)

(73) Assignee: Daishinku Corporation, Kakogawa-shi, Hyogo (JP)

(21) Appl. No.: 15/527,795

(22) PCT Filed: Sep. 29, 2015
(86) PCT No.: PCT/JP2015/077489

§ 371 Date: May 18, 2017

(30) Foreign Application Priority Data
Nov. 21, 2014 (JP) 2014-236089

(51) Int. Cl. H01L 41/09; H01L 41/047; H03H 9/05; H03H 9/13

(52) U.S. Cl. CPC H01L 41/0913; H01L 41/0472; H03H 9/132; H03H 9/0595; H01L 41/0475

(57) ABSTRACT

A piezoelectric resonator device adapted to miniaturization while saving a region to be bonded to an external circuit board is provided, which includes an external connection terminal with a highly recognizable distinguishing mark. A crystal resonator 1 includes: a base 2 having a substrate 20, a first frame 21 and a second frame 22; a crystal resonator element 3 housed in a first recessed portion E1; a thermistor 4 housed in a second recessed portion E2; and a lid 5 hermetically sealing the first recessed portion E2. L-shaped external connection terminals 9a to 9d are respectively formed at four corners of a top surface of the second frame. Non-electrode bank regions 9e, 9f, 9g and 9h are formed between respective inner edges of the external connection terminals at the four corners and an inner peripheral edge 221 of the second frame. On the external connection terminal 9c, a protrusion 92c is formed spaced apart from an outer peripheral edge 220 and the inner peripheral edge 221 of the second frame.

### TECHNICAL FIELD

The present invention relates to a surface mount type piezoelectric resonator device.

### BACKGROUND ART

As a piezoelectric resonator device, for example, a surface mount type crystal resonator or a surface mount type crystal oscillator is widely used. For example, the surface mount type crystal oscillator has a configuration in which: a piezoelectric resonator element made of a crystal and the like and an electronic component such as an integrated circuit element are mounted in a recessed portion formed in a base (package) made of an insulating material; and the recessed portion is hermetically sealed by a lid. On an outer bottom surface of the base, a plurality of external connection terminals is formed. Parts of the external connection terminals are electrically connected to the piezoelectric resonator element and the electronic component. The piezoelectric resonator device is mounted on an external circuit board by electrically and mechanically connecting the external connection terminals, with a conductive bonding material such as a solder, to pads mounted on the external circuit board.

Among the above-described piezoelectric resonator devices, there are devices having a so-called H-type package structure in which a crystal resonator element and an electronic component are respectively housed in separated spaces as disclosed, for example, in Patent Document 1. Specifically, in the crystal oscillator described in Patent Document 1, a crystal piece (piezoelectric resonator element) is encapsulated in one of the two cavities (recessed portions) formed respectively in a surface and a rear surface of the package, and an IC chip (electronic component) is mounted in the other cavity. External connection terminals are formed at four corners of a top surface of a frame portion surrounding the cavity in which the IC Chip is mounted (i.e., on a bottom surface of the crystal oscillator).

As described in Patent Document 1, this type of piezoelectric resonator device includes, generally, a distinguishing mark (protrusion) formed by protruding a part of the external connection terminal in order to distinguish the mounting direction of the piezoelectric resonator device relative to the external circuit board and also to distinguish the kinds of the respective external connection terminals to be connected to the external circuit board.

### PRIOR ART DOCUMENT

### Patent Document

[Patent Document 1] JP 2009-027469 A

### SUMMARY OF THE INVENTION

### Problem to be Solved by the Invention

As described above, in an piezoelectric resonator device having the H-type package structure, the cavity in which an electronic component (IC chip) is mounted constrains the area of the outer bottom surface of the base, which results in the area being relatively small compared with that of a flat outer bottom surface of a base in which no cavity is formed. Thus, the position and the area of the external connection terminals that can be formed on the top surface (outer bottom surface) of the frame are also restricted, which makes it difficult to save a bonding region for bonding the external connection terminals to the external circuit board while preventing short-circuiting among the external connection terminals.

Especially in the piezoelectric resonator device having the H-type package structure and including a distinguishing mark formed by protruding a part of an external connection terminal on the top surface (outer bottom surface) of the frame, it is required to form the external connection terminals so as not to cause short-circuiting between the electronic component mounted in the cavity when bonding the external connection terminals to the external circuit board with a conductive bonding material. In addition, it is needed to form the distinguishing mark only on the top surface, whose area is relatively small, of the frame while preventing degradation in recognizability of the distinguishing mark. These technical problems has become apparent following miniaturization of the piezoelectric resonator device.

The present invention was made in consideration of the above circumstances, an object of which is to provide a piezoelectric resonator device that is adapted to miniaturization, and that has an external connection terminal with a highly recognizable distinguishing mark while saving a bonding region to be bonded to an external circuit board.

### Means for Solving the Problem

In order to achieve the above object, the present invention provides a piezoelectric resonator device including: a base that has a substantially rectangular shape in plan view and that includes a first recessed portion formed in a first main surface so as to house a piezoelectric resonator element and a second recessed portion formed in a second main surface so as to house an electronic component; and four external connection terminals formed at four corners of the second main surface of the base. Each of the external connection terminals includes: a first portion that extends along a short side direction of the base; and a second portion that extends along a long side direction of the base, and the first portion and the second portion are connected to each other at the corresponding corner of the base. Each of the external connection terminals is positioned spaced apart from an outer peripheral edge of the second recessed portion. At least one of the external connection terminals includes a protrusion protruding from an end portion of the first portion of the at least one external connection terminal toward the center in the short side direction of the base, and the protrusion is formed spaced apart from an outer peripheral edge of the base and the outer peripheral edge of the second recessed portion. Particularly, the base includes: a substrate; a first frame extending upward from an outer peripheral portion of the first main surface of the substrate; and a second frame extending downward from an outer peripheral portion of the second main surface of the substrate. The first recessed portion is surrounded by the first frame and the first main surface of the substrate while the second recessed portion is surrounded by the second frame and the second main surface of the substrate. Each of the external connection terminals is formed so as to have a substantially L-shape, and each non-electrode bank region that has no external connection terminal electrode thereon is formed between an inner edge of the corresponding external connection terminal and an inner peripheral edge of the second frame. The protrusion is formed spaced apart from an outer peripheral edge and the inner peripheral edge of the second frame.

With the above-described configuration, in the piezoelectric resonator device having the H-type package structure, each of the external connection terminals at the four corners is formed so as to have a substantially L-shape along the directions of the respective sides of the outer peripheral edge and the inner peripheral edge of the second frame. Thus, it is possible to ensure the area on which the external connection terminals are formed even when the above area for the external connection terminals is restricted due to the second recessed portion, which prevents reduction in the bonding strength to the external circuit board.

Also, since the respective non-electrode bank regions that have no external connection terminal electrode thereon are formed between the respective inner edges of the external connection terminals at the four corners and the inner peripheral edge of the second frame, it is possible to ensure insulating regions as the non-electrode bank regions so that the inner edges of the external connection terminals as well as the protrusion are spaced apart from the edge portion of the second recessed portion. Thus, the external connection terminals are spaced apart from the electronic component housed in the second recessed portion with the insulating regions being interposed therebetween, which prevents short-circuiting of the external connection terminals and the electronic component due to the conductive bonding material for bonding the external circuit board and the external connection terminals.

Also, the protrusion, which is formed on at least one of the external connection terminals at the four corners so as to serve as a distinguishing mark, is formed in the short side direction of the outer peripheral edge of the second frame in a state of being spaced apart from the outer peripheral edge and the inner peripheral edge of the second frame. Thus, the protrusion of the external connection terminal can also be maintained in the state of being spaced apart from the electronic component housed in the second recessed portion. For this reason, it is possible to prevent short-circuiting of the protrusion as the distinguishing mark of the external connection terminals and the electronic component due to the conductive bonding material. Since the protrusion of the external connection terminal is formed in a state of not making contact with the outer peripheral edge and the inner peripheral edge of the second frame, it is possible to prevent, when performing image recognition, an image from being indistinct caused by overlapping of either of the outer peripheral edge or the inner peripheral edge of the second frame with the protrusion of the external connection terminal. Thus, the image recognition becomes easy, which also improves easiness in recognition of the distinguishing mark.

Also, the above-described configuration is suitable for a piezoelectric resonator device in which the electronic component is bonded to the base with the conductive bonding material. In this case, in addition to the above-described functions and effects, the external connection terminals are spaced apart from the electronic component that is housed in the base (second recessed portion) with the respective insulating regions being interposed therebetween, which makes possible to prevent short-circuiting of the external connection terminals and the electronic component due to the conductive bonding material for bonding the electronic component to the base (second recessed portion).

In the above-described configuration, the electronic component may be in a substantially rectangular shape having a long side and a short side in plan view, and the electronic component may be housed in the second recessed portion in a state in which the long side of the electronic component is in parallel with the short side direction of the base. In this case, in addition to the above-described functions and effects, it is possible to dispose the inner edges of the external connection terminals at the four corners further spaced apart from the electronic component that is housed in the second recessed portion. For this reason, it is possible to prevent short-circuiting of the external connection terminals and the electronic component due to the conductive bonding material.

In the above-described configuration, the external connection terminals may include: a pair of external connection terminals for piezoelectric resonator element, which is to be electrically connected to the piezoelectric resonator element; and a pair of external connection terminals for electronic component, which is to be electrically connected to the electronic component. Furthermore, the protrusion may be formed on one of the pair of external connection terminals for piezoelectric resonator element. In this case, in addition to the above-described functions and effects, this external connection terminal for the piezoelectric resonator element can have a plane area larger than the other external connection terminals because of the protrusion formed on the external connection terminal for this piezoelectric resonator element. Thus, when electrical characteristics of the piezoelectric resonator device are measured by a contact probe to be contacted with this external connection terminal, it is possible to prevent this external connection terminal for piezoelectric resonator element from being affected by contact error of the contact probe, which makes possible to ensure further stable electrical characteristics.

### Effect of the Invention

In this way, it is possible to provide a piezoelectric resonator device having the H-type package structure that is adapted to miniaturization, and that has an external connection terminal with a highly recognizable distinguishing mark while saving a bonding region to be bonded to an external circuit board.

### BRIEF DESCRIPTION OF THE DRAWINGS

FIG. 1 is a cross-sectional view showing a schematic configuration of a crystal resonator according to an embodiment of the present invention.

FIG. 2 is a bottom view showing a schematic configuration of the crystal resonator according to the embodiment of the present invention.

### MODES FOR CARRYING OUT THE INVENTION

Hereinafter, description will be given on an embodiment of the present invention with reference to the drawings. In the embodiment of the present invention stated below, a surface mount type crystal resonator having a built-in thermistor is exemplarily described as a piezoelectric resonator device.

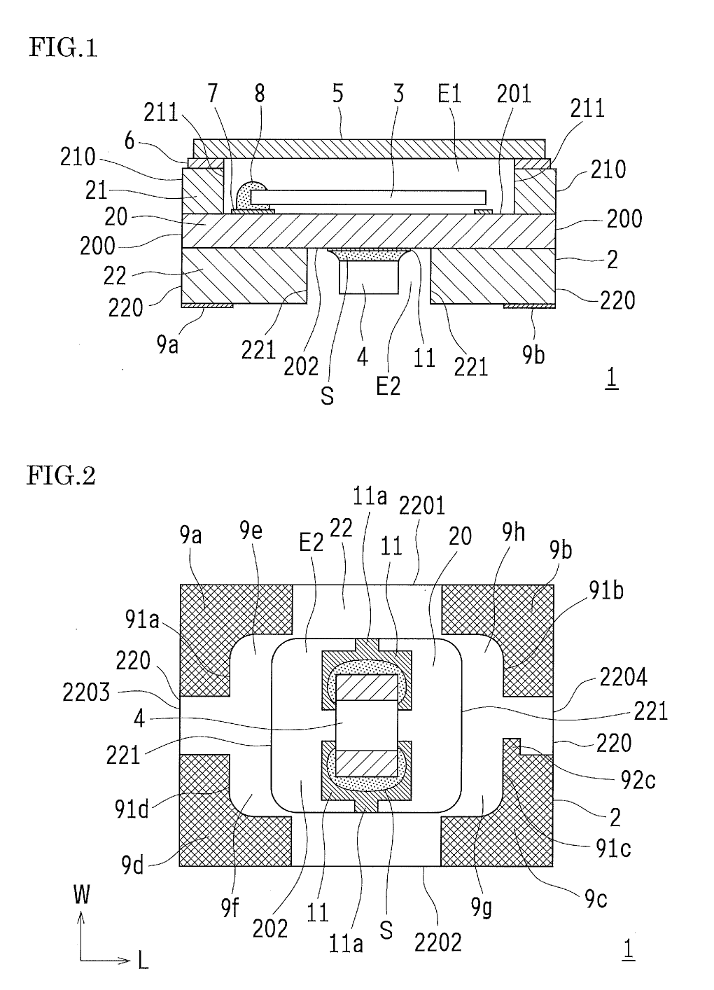

The embodiment of the present invention is described using FIGS. 1 and 2. In FIG. 1, a crystal resonator 1 is a package having a substantially rectangular parallelepiped shape, which has also a substantially rectangular shape in plan view. The crystal resonator 1 includes, as main components: a base 2; a crystal resonator element 3; a thermistor 4; and a lid 5. In this embodiment, the crystal resonator 1 has an external dimensions of 2.5 mm×2.0 mm in length and breadth in plan view, and has an oscillating frequency of 19.2 MHz. The crystal resonator 1 has a built-in thermistor 4 as an electronic component. Based on temperature information obtained from the thermistor 4, a temperature compensation is executed outside. Note that the above external dimensions in plan view and the above oscillating frequency of the crystal resonator 1 are exemplarily shown. The present invention can be applied to a crystal resonator having the package size other than the above external dimensions or having the frequency other than the above oscillating frequency. Hereinafter, each component that constitutes the crystal resonator 1 is outlined, and then, external connection terminals provided on the crystal resonator 1 will be described in detail.

In FIGS. 1 and 2, the base 2 is a case made of an insulating material. The base 2 is formed in a substantially rectangular shape in plan view, having a long side and a short side. The base 2 includes, as main components: a flat-plate like substrate 20 (i.e., having a substantially rectangular shape in plan view); a first frame 21 extending upward along an outer peripheral portion 200 of a first main surface 201 of the substrate 20 so that an outer peripheral edge 210 and an inner peripheral edge 211 each have a substantially rectangular shape in plan view; and a second frame 22 extending downward along the outer peripheral portion 200 of a second main surface 202 of the substrate 20 so that an outer peripheral edge 220 and an inner peripheral edge 221 each have a substantially rectangular shape in plan view. In this embodiment, the substrate 20, the first frame 21 and the second frame 22 are each made of a ceramic green sheet (alumina), and these three sheets are laminated and baked, thus integrally formed. Between each laminated sheet, internal wiring having a predetermined shape is formed.

A first recessed portion E1 is a space that is surrounded by the inner peripheral edge 211 of the first frame 21 of the base 2 and the first main surface 201 of the substrate. The first recessed portion E1 has a substantially rectangular shape in plan view, and has the same shape as the inner peripheral edge 211 of the first frame 21. On one side of the inner bottom surface of the first recessed portion E1, a pair of crystal mounting pads 7 and 7, which is conductively bonded to the crystal resonator element 3, is formed in parallel with each other (in FIG. 1, only one of them is shown). On the crystal mounting pads 7, one end portion of the crystal resonator element 3 is conductively bonded with a conductive adhesive 8.

A second recessed portion E2 is a space that is surrounded by the inner peripheral edge 221 of the second frame 22 of the base 2 and the second main surface 202 of the substrate. The second recessed portion E2 has a square shape in plan view, and has the same shape as the inner peripheral edge 221 of the second frame 22. The second recessed portion E2 is smaller than the first recessed portion E1 in plan view. As the positional relation thereof in perspective plan view, the second recessed portion E2 is included in the first recessed portion E1. The shape of the second recessed portion E2 in plan view is not limited thereto. For example, it may have a rectangular shape.

On the inner bottom surface of the second recessed portion E2, a pair of thermistor mounting pads 11 and 11 is formed so as to face each other, which is conductively bonded to the thermistor 4 in a substantially rectangular shape having a long side and a short side in plan view. The pair of thermistor mounting pads 11 and 11 is connected, respectively, to a pair of extraction electrodes 11a and 11a. The pair of extraction electrodes 11a and 11a is electrically connected, respectively, to external connection terminals 9b and 9d for the thermistor via the inner wiring. On the pair of thermistor mounting pads 11 and 11, respective electrodes of both end portions of the thermistor 4 are conductively bonded with a solder S.

In this embodiment of the present invention, the thermistor 4 is housed in the second recessed portion E2 so that the long side direction (direction indicated with sign W in FIG. 2) of the thermistor 4 is in parallel with the short side direction (specifically, short sides 2203 and 2204) of the outer peripheral edge 220 of the second frame 22 (base 2). In this way, the end portions of the thermistor 4 can be positioned further spaced apart from respective inner edges 91a, 91b, 91c and 91d of the external connection terminals 9a, 9b, 9c and 9d (described later) at the four corners. Thus, it is possible to avoid short-circuiting of the thermistor 4 and the external connection terminals 9a, 9b, 9c and 9d due to the solder S (conductive bonding material). The positional direction of the thermistor 4 is not limited thereto. For example, the thermistor 4 may be positioned so that the long side direction of the thermistor 4 is orthogonal to the short side direction of the outer peripheral edge 220 of the second frame 22 (base 2).

The base 2 used in this embodiment of the present invention has the H-type package structure as described above. In such a package structure, since the crystal resonator element 3 and the thermistor 4 are housed in the respective spaces separately from each other, it is possible to prevent the crystal resonator 1 from being affected by gas generated in the manufacturing process or by noise generated by other elements. Also, since the crystal resonator element 3 and the thermistor 4 are housed in one base 2 with being adjacent to each other, it is possible to reduce the difference between the actual temperature of the crystal resonator element 3 and the measured value by the thermistor 4. Furthermore, the crystal resonator 1 having the built-in thermistor according to this embodiment of the present invention is a no-temperature-compensation device that does not include any temperature compensation circuit. Thus, it is possible to obtain good phase noise characteristics.

Onto the top surface of the first frame 21 of the base 2, a metal ring 6 made of kovar is attached. The metal ring 6 is bonded to the metal lid 5 using the seam welding method.

In FIG. 1, the crystal resonator element 3 is a piezoelectric resonator element having a rectangular shape in plan view, which is made by forming various electrodes on a main surface and a rear main surface of an AT cut crystal resonator plate. Note that the various electrodes are omitted in FIG. 1. On a surface and a rear surface of the substantially center portion of the crystal resonator plate, excitation electrodes are respectively formed so as to face each other, although they are also omitted in FIG. 1. Extraction electrodes are each extracted from the respective excitation electrodes toward an edge of one short side of the main surface/rear main surface of the crystal resonator plate. A terminal portion of each extraction electrode serves as an electrode for bonding, which is to be bonded to the above-described crystal mounting pad 7 with the conductive adhesive 8. In this embodiment, a silicone adhesive is used as the conductive adhesive 8, however, it is possible to use a conductive adhesive other than the silicone adhesive.

The thermistor 4 used in this embodiment is a so-called NTC thermistor (i.e., negative temperature coefficient thermistor) whose resistance value decreases as the temperature increases. In this embodiment, a chip type thermistor is used in accordance with miniaturization of the piezoelectric resonator device. In FIG. 2, the thermistor 4 has a substantially rectangular parallelepiped shape, and has the dimensions of 0.6 mm×0.3 mm in plan view (substantially rectangular shape having a long side and a short side in plan view). The above size of the thermistor 4 in this embodiment is exemplarily shown, and a thermistor other than the above size may be used.

In FIG. 1, the lid 5 is a flat plate having a substantially rectangular shape in plan view. The lid 5 is made of kovar as the base material, and nickel plating is applied on surfaces of the base material. The respective components were thus outlined.

Next, the configuration of the external connection terminals, which is a characteristic feature of the present invention, will be described with reference to FIG. 2. The outer peripheral edge of the top surface (bottom surface of the base 2) of the second frame 22 has a substantially rectangular shape in plan view. On the top surface of the second frame 22, the external connection terminals 9a, 9b, 9c and 9d are formed respectively at the four corners of the rectangle. Each of the external connection terminals 9a, 9b, 9c and 9d is formed so as to have a substantially L-shape along the directions of respective sides of the outer peripheral edge 220 and the inner peripheral edge 221 of the second frame 22. Each of the external connection terminals 9a, 9b, 9c and 9d has a first portion that extends along the short side direction of the second frame 22 (base 2) and a second portion that extends along the long side direction of the second frame 22 (base 2). The first portion and the second portion are connected to each other at the corresponding corner of the second frame 22 (base 2). Regarding the external connection terminals 9a, 9b, 9c and 9d, the inner edges 91a, 91b, 91c and 91d facing the inner peripheral edge 221 of the second frame 22 are formed in a state in which they are shifted in parallel so that they are spaced apart from the inner peripheral edge 221 of the second frame 22 only toward both end directions of the long sides 2201 and 2202 (i.e., toward the short sides 2203 and 2204) out of the outer peripheral edge 220 of the second frame 22. At this time, the long side direction of the outer peripheral edge of the second frame (long sides 2201 and 2202) is the same direction as the long side direction of the base 2 indicated with sign L in FIG. 2, while the short side direction (short sides 2203 and 2204) of the outer peripheral edge 220 of the second frame 22 is the same direction as the short side direction of the base 2 indicated with sign W in FIG. 2.

The external connection terminals 9a, 9b, 9c and 9d are formed so as to be shifted as described above, accordingly, non-electrode bank regions 9e, 9f, 9g and 9h that have no external connection terminal electrode thereon are formed between the inner edges 91a, 91b, 91c and 91d of the external connection terminals 9a, 9b, 9c and 9d and two sides 2211 and 2212 of the inner peripheral edge 221 of the second frame 22, the two sides being in parallel with the short side 2201 and 2202 of the outer peripheral edge 220 of the second frame 22. In this embodiment of the present invention, it is possible to ensure insulating regions as the non-electrode bank regions 9e, 9f, 9g and 9h so that the inner edges 91a, 91b, 91c and 91d of the external connection terminals 9a, 9b, 9c and 9d are spaced apart from the inner peripheral edge 221 (edge portion of the second recessed portion E2) of the second frame 22. Thus, the external connection terminals 9a, 9b, 9c and 9d are spaced apart from the thermistor 4 housed in the second recessed portion E2 with the insulating regions being interposed therebetween, which prevents short-circuiting of the thermistor 4 and the external connection terminals 9a, 9b, 9c and 9d due to the conductive bonding material such as a solder for bonding the external circuit board and the external connection terminals. This embodiment of the present invention is suitable for a crystal resonator in which an electronic component such as the thermistor 4 is bonded to the second recessed portion E2 of the base 2 using the conductive bonding material such as a solder, which can be further easily adapted to miniaturization.

Also, the external connection terminal 9c, which is one of the external connection terminals 9a, 9b, 9c and 9d at the four corners, includes a protrusion 92c protruding from the end portion of the external connection terminal 9c toward the center in the short side direction (center of the short side 2204) of the outer peripheral edge 220 of the second frame 22. The protrusion 92c is formed in a rectangular shape in plan view. The protrusion 92c is formed spaced apart from the outer peripheral edge 220 and the inner peripheral edge 221 of the second frame 22 so as not to make contact with the outer peripheral edge 220 and the inner peripheral edge 221 of the second frame 22. In this embodiment of the present invention, the protrusion 92c of the external connection terminal 9c serves as a mark, which makes possible to distinguish the directions and kinds of the external connection terminals 9a, 9b, 9c and 9d of the surface mount type crystal resonator 1 of the present invention. Thus, it functions effectively when the crystal resonator 1 is mounted on an external circuit board. In addition, the protrusion 92c of the external connection terminal 9c can also be maintained in the state of being spaced apart from the thermistor 4 housed in the second recessed portion E2. For this reason, it is possible to prevent short-circuiting of the thermistor 4 and the protrusion 92c as the distinguishing mark of the external connection terminals 9a, 9b, 9c and 9d due to the conductive bonding material such as a solder. Since the protrusion 92c of the external connection terminal 9c is formed in a state of not making contact with the outer peripheral edge 220 and the inner peripheral edge 221 of the second frame 22, it is possible to prevent, when performing image recognition, an image from being indistinct caused by overlapping of either of the outer peripheral edge 220 or the inner peripheral edge 221 of the second frame 22 with the protrusion 92c of the external connection terminal 9c. Thus, the image recognition becomes easy, which also improves easiness in recognition of the distinguishing mark. These four external connection terminals 9a, 9b, 9c and 9d are bonded, with the solder, to an external circuit board (not shown). The protrusion 92c may have a shape in plan view other than the rectangle (for example, it may have a semicircular or a triangular shape).

In this embodiment, all of the four external connection terminals 9a, 9b, 9c and 9d are configured by laminating three kinds of metals. Specifically, the external connection terminals 9a, 9b, 9c and 9d have a configuration in which a tungsten layer is formed on the base material (ceramic) of the base 2 by printing process, and a nickel plating layer and a gold plating layer are respectively laminated, in this order, on the tungsten layer. The nickel plating layer and the gold plating layer are formed by electroplating, and the external connection terminals 9a, 9b, 9c and 9d, pads and the like are integrally and simultaneously formed.

Out of the four external connection terminals 9a, 9b, 9c and 9d, the external connection terminals 9a and 9c are electrically connected, respectively, to the excitation electrodes on the main surface/rear main surface of the crystal resonator element 3. The remaining external connection terminals 9b and 9d are electrically connected, respectively, to the electrodes of both end portions of the thermistor 4. That is, the external connection terminals 9a and 9c are the external connection terminals for the crystal resonator element while the external connection terminals 9b and 9d are the external connection terminals for the thermistor. Here, the external connection terminals 9a and 9c for the crystal resonator element are not electrically connected to the external connection terminals 9b and 9d for the thermistor, which means that the former and the latter are independent from each other. Thus, the external connection terminals 9a and 9c are electrically connected to only the excitation electrodes of the crystal resonator element 3 while the external connection terminals 9b and 9d are electrically connected to only the terminal electrodes of the thermistor 4.

Although it is not shown in the drawings, the external connection terminal 9d is connected, via the inner wiring formed on the base 2, to a via hole that is filled with conductor and that penetrates the inside of the first frame 21, the substrate 20 and the second frame 22. One end of the via hole is electrically connected to the metal ring 6 of the top surface of the first frame 21. That is, the metal lid 5 and the external connection terminal 9d can be ground connected, which allows to obtain the shield effect.

It is necessary to reduce the size of the second recessed portion E2 with miniaturization of the piezoelectric resonator device. However, taking into account the size or the mountability of the electronic component such as the thermistor 4 or the IC, it is also necessary to ensure a certain size as the second recessed portion E2. As a result, the width of the dike portion of the second frame 22 is decreased, the second frame 22 in which the electronic component is mounted. The mechanical strength of the base 2 is relatively reduced because of decrease of the width of the dike portion of the second frame 22. In the present invention, each of the external connection terminals 9a, 9b, 9c and 9d at the four corners is formed so as to have a substantially L-shape along the directions of the respective sides of the outer peripheral edge 220 and the inner peripheral edge 221 of the second frame 22. Thus, it is possible to ensure the area on which the external connection terminals 9a, 9b, 9c and 9d are formed even when the above area for the external connection terminals is restricted due to the second recessed portion E2, which prevents reduction in the bonding strength to the external circuit board.

In this embodiment of the present invention as described above, the thermistor 4 is used as a thermosensitive element. However, a thermosensitive element other than the thermistor 4 may also be used. For example, it is possible to use a diode in place of the thermistor. Also, in this embodiment, the crystal resonator having a built-in thermistor was exemplarily described. However, the present invention can also be applied to a piezoelectric oscillator such as a temperature compensation type crystal oscillator that has a built-in IC, a built-in temperature compensation circuit or the like as the electronic component. Also, in this embodiment, the configuration in which the first frame 21 is laminated on the first main surface 201 of the substrate 20 was described. However, a ring-shaped member made of a metal may be attached, in place of the first frame 21, to the first main surface 201 of the substrate 20.

The present invention can be embodied in other forms without departing from the spirit or essential characteristics thereof. The foregoing embodiments are therefore to be considered in all respects as illustrative and not restrictive. The scope of the present invention is indicated by the appended claims rather than by the foregoing description. Furthermore, all modifications and changes that come within the meaning and range of equivalency of the claims are intended to be embraced therein.

This application claims priority on Patent Application No. 2014-236089 filed in Japan on Nov. 21, 2014. The entire contents thereof are hereby incorporated in this application by reference.

### INDUSTRIAL APPLICABILITY

The present invention can be applied in mass production of piezoelectric resonator devices.

### DESCRIPTION OF REFERENCE NUMERALS

1 Crystal resonator
2 Base
3 Crystal resonator element
4 Thermistor
5 Lid
6 Metal ring
7 Crystal mounting pad
8 Conductive adhesive
11 Thermistor mounting pad
20 Substrate
21 First frame
22 Second frame
9a to 9d External connection terminal
9e to 9h Non-electrode bank region

1. A piezoelectric resonator device comprising:
a base having a substantially rectangular shape in plan view, the base including a first recessed portion formed in a first main surface so as to house a piezoelectric resonator element, and a second recessed portion formed in a second main surface so as to house an electronic component; and
four external connection terminals formed at four corners of the second main surface of the base,
wherein each of the external connection terminals includes: a first portion that extends along a short side direction of the base; and a second portion that extends along a long side direction of the base, and the first portion and the second portion are connected to each other at the corresponding corner of the base,
wherein each of the external connection terminals is positioned spaced apart from an outer peripheral edge of the second recessed portion, and
wherein at least one of the external connection terminals includes a protrusion protruding from an end portion of the first portion of the at least one external connection terminal toward a center in the short side direction of the base, and the protrusion is formed spaced apart from an outer peripheral edge of the base and the outer peripheral edge of the second recessed portion.

2. The piezoelectric resonator device according to claim 1,
wherein the base includes: a substrate; a first frame extending upward from an outer peripheral portion of the first main surface of the substrate; and a second frame extending downward from an outer peripheral portion of the second main surface of the substrate,
wherein the first recessed portion is surrounded by the first frame and the first main surface of the substrate while the second recessed portion is surrounded by the second frame and the second main surface of the substrate,
wherein each of the external connection terminals is formed so as to have a substantially L-shape, and each non-electrode bank region that has no external connection terminal electrode thereon is formed between an inner edge of the corresponding external connection terminal and an inner peripheral edge of the second frame, and
wherein the protrusion is formed spaced apart from an outer peripheral edge and the inner peripheral edge of the second frame.

3. The piezoelectric resonator device according to claim 1,
wherein the electronic component is bonded to the base with a conductive bonding material.

4. The piezoelectric resonator device according to claim 1,
wherein the electronic component is in a substantially rectangular shape having a long side and a short side in plan view, and
wherein the electronic component is housed in the second recessed portion in a state in which the long side of the electronic component is in parallel with the short side direction of the base.

5. The piezoelectric resonator device according to claim 1,
wherein the external connection terminals include: a pair of external connection terminals for piezoelectric resonator element, the pair of external connection terminals being electrically connected to the piezoelectric resonator element; and a pair of external connection terminals for electronic component, the pair of external connection terminals being electrically connected to the electronic component, and
wherein the protrusion is formed on one of the pair of external connection terminals for piezoelectric resonator element.
